(19) United States
(12) Patent Application Publication
(10) Pub. No.: US 2026/0164563 A1
(43) Pub. Date: Jun. 11, 2026

(54) FABRICATING STRETCHABLE LIQUID METAL CIRCUITS WITH A PHYSICAL SACRIFICIAL LAYER

(71) Applicant: University of Massachusetts, Westborough, MA (US)

(72) Inventors: Tingyi Liu, Amherst, MA (US); Kaushal J. Sumaria, Amherst, MA (US)

(73) Assignee: University of Massachusetts, Westborough, MA (US)

(21) Appl. No.: 19/411,496

(22) Filed: Dec. 8, 2025

Related U.S. Application Data
(60) Provisional application No. 63/728,853, filed on Dec. 6, 2024.

(51) Int. Cl. H05K 3/10; B33Y 80/00; H05K 1/02; H05K 1/03; H05K 3/12; H05K 3/20

(52) U.S. Cl. CPC H05K 3/107; H05K 1/0277; H05K 1/0306; H05K 3/1216; H05K 3/20; B33Y 80/00

(57) ABSTRACT

Stretchable electronics with mechanical properties compatible with biological systems enable emerging applications such as continuous physiological monitoring, neural sensing and modulation, and programmable mechanoreceptors is disclosed. Here, we introduce a physical sacrificial layer strategy that significantly accelerates and simplifies the fabrication of stretchable electronics. By using poly(vinyl alcohol) (PVA) as a physical sacrificial layer, devices can be rapidly released through manual peeling followed by direct contact etching in 2 minutes irrespective of the area. This approach not only offers exponential speed improvements over traditional methods but is also broadly applicable to existing stretchable electronics fabrication processes. Furthermore, it enables vertical interconnect access (VIA) and interposers to integrate diverse electronic components, modules, and systems on different scales. To demonstrate its versatility, we demonstrate stretchable circuits featuring integration between soft circuit, surface mount components and human interaction underscoring its potential for rapid implementation of sophisticated heterogeneously integrated stretchable electronic systems.

### CROSS-REFERENCE TO RELATED APPLICATIONS

This patent document claims priority to earlier filed U.S. Provisional Patent Application Ser. No. 63/728,853, filed on Dec. 6, 2024, the entire contents of which are incorporated herein by reference.

### STATEMENT REGARDING FEDERALLY SPONSORED RESEARCH OR DEVELOPMENT

This invention was made with government support under EB033599 awarded by the National Institutes of Health, and 2430855 awarded by the National Science Foundation. The government has certain rights in the invention.

### BACKGROUND OF THE INVENTION

### 1. Field of the Invention

The present patent document is directed to methods of manufacturing flexible circuits and more particularly to an improved method of manufacturing stretchable, flexible circuits that includes a physical sacrificial layer.

### 2. Background of the Related Art

Stretchable electronics are catalysts for enabling advancements in various fields such as robotics, prosthetics, wearable and implantable devices, and brain-machine or human-machine interfaces. Stretchable electronics provide favorable material properties and soft form-factor which can be manipulated easily to conformably interface with similar systems for example skin, tissues, organs, etc. It is rare to find conductive material that can satisfy the requirement of soft form-factor as well as superior electrical performance. Liquid metals (“LM”), such as gallium and its alloys, offer a promising solution for stretchable electronics. LMs are non-toxic, naturally occur in a liquid state, and exhibit excellent electrical conductivity. Despite these favorable properties, patterning LM at the microscale remains challenging due to the rapid formation of a thin oxide skin on its surface and high surface tension. Several techniques have been explored to pattern LM, including screen printing, selective wetting on metal traces, microfluidics, and 3D printing.

While these methods have successfully yielded stretchable electronics, they have primarily been limited to stretchable wires that make up in plane interconnects in a circuit or to individual components such as resistors or capacitors, mainly for sensing applications. They lack more complex, system-level integration as they cannot readily integrate with surface-mount devices (“SMDs”) or microcontrollers that convert circuits into systems. Researchers have demonstrated intrinsically stretchable transistors, but they involve complex and expensive processing steps and remain far from the complexity achieved by mass-manufactured and silicon based integrated circuit and microcontrollers. The mature printed circuit board (“PCB”) technology is widely implemented due to its ability to easily integrate with SMDs through direct pick-and-place and solder processes. Moreover, the complexities of the IC and PCB circuits can be tuned by using multilayer architecture, where interlayer connections are achieved through vertical interconnect access (VIA) created by drilling holes through the PCB layers. Since soft circuits are fabricated layer by layer, alternating between conductive and encapsulating layers, it is intrinsically difficult to drill high-resolution and precisely controlled holes without damaging the circuit, thereby limiting the overall complexity of soft circuits. Further, the holes are often filled with conductive epoxies, which differ in mechanical properties from the circuit and become sources of stress concentration and failures.

### SUMMARY OF THE INVENTION

To bridge the gap between stretchable circuits and their integration with external components into fully stretchable systems, we present a universal strategy compatible with all existing LM patterning methods used to fabricate stretchable electronics. We introduce a flexible physical sacrificial layer on which the device is patterned and encapsulated using standard processes. This layer serves as a temporary substrate and packaging for the LM circuits, and also assists in the handling of the soft, fragile stretchable layers. The fully encapsulated conductive LM is inaccessible for external integration. Using the flexible sacrificial layer, the device is peeled from the substrate and flipped upside down such that the sacrificial layer faces upward. The physical sacrificial layer is then etched rapidly to expose the LM, enabling direct pick-and-place integration to form a stretchable electronic system. This approach eliminates the complicated fabrication processes required for VIA fabrication by directly expose the LM for direct contact and integration with SMDs. Unlike traditional sacrificial layers, the physical sacrificial-layer approach eliminates the slow undercut etching step required to release devices. This avoids a time-consuming process and prevents the capillary forces and stiction that often damage LM circuits.

### BRIEF DESCRIPTION OF THE DRAWINGS

These and other features, aspects, and advantages of the present invention will become better understood with reference to the following description, appended claims, and accompanying drawings where:

FIG. 1 shows a schematic diagram of the process flow to fabricate LM-based stretchable electronics using physical sacrificial PVA layer and corresponding process documented on a LM coil, wherein the LM coil pattern can be created with any existing LM patterning method including but not limited to microfluidics, screen printing, and 3D printing;

FIG. 2 shows an embodiment of the method where (a) PDMS and LM circuit bonded to PVA layer peeled off without crumbling or deformation while (b) robustly packaging the LM inside the microchannels under extreme deformations such as 360° curving;

FIG. 3 shows a series of timelapse images of etching time characterization for PVA layer by direct contact of de-ionized water (DIW) compared to the conventional undercut etching, where the PVA is contrasted to track the progress of etching;

FIG. 4 shows juxtaposed charts of (a) comparison of process time when PVA is etched using direct contact etching compared to undercut etching and (b) expected PVA etching times when scaled to a typical wafer-level MEMS process;

FIG. 5 shows an illustration of yield comparison for direct contact etching and undercut etching method employed to etch PVA;

FIG. 6 shows SEM and EDS characterization of (a) PVA covering the LM, and (b) exposed LM after PVA etching; where the element map (c) changes from C and O to Ga after the PVA is etched;

FIG. 7 shows graphs of simultaneous dynamic testing as well as resistance measurement demonstrating the robustness of the LM circuit fabricated by the physical sacrificial layer method;

FIG. 8 shows a schematic of rapid prototyping of stretchable circuits according to an embodiment of the method shows herein, where LM circuit modules integrated with electronic components (LED) as well as integration between LM circuit modules;

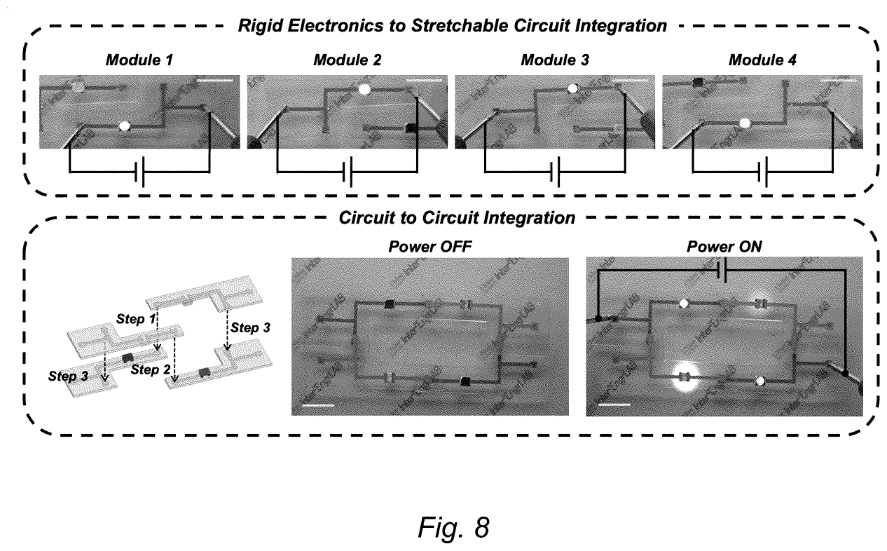

FIG. 9 shows juxtaposed images of (Top) integrating LMμD and bulk LM modules (Bottom) interposer device with fourteen layers stacked on top of each other;

FIG. 10 shows images of (a) heterogenous integration of IC packaged SMD components with exposed LM wires exposed by direct contact PVA etching; and a stretchable LED display under (b) bending, (c) tensile, neutral, and compressive stress; and (d) shows a “UMASS” pattern formed by selectively lighting up individual LEDs in the array;

FIG. 11 shows illustrations of (a) top view of the capacitor sensor; (b) schematic and (c) electrical model of an object's interaction with the capacitor sensor and corresponding change in the capacitance; (d) metal ball placed at different locations identified by the sensor data; (e) single and multi-location touch sensing; (f) De-ionized water location sensing; and (g) measured capacitance on pixel at (5,2) due to a NaCl solution; and

FIG. 12 shows a diagram of surface electromyography using LMμD electrodes successfully identifying various gestures.

### DESCRIPTION OF THE PREFERRED EMBODIMENT

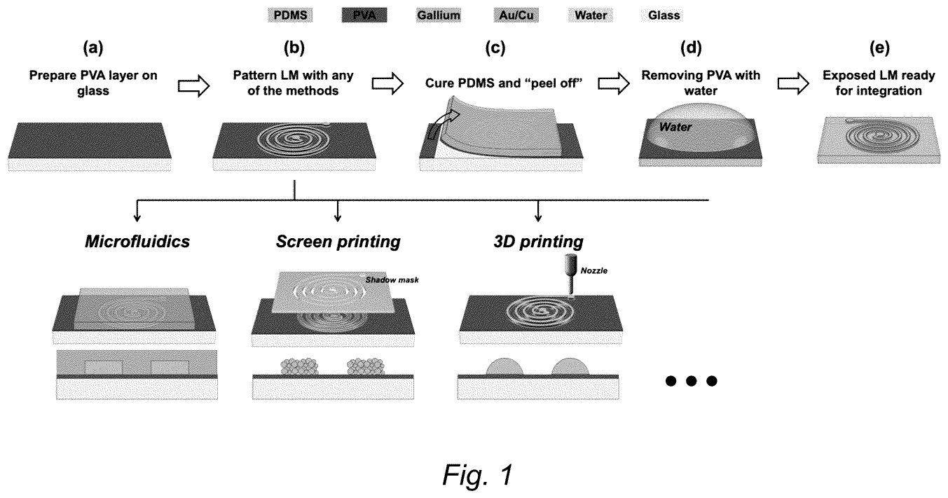

FIG. 1 illustrates the schematic of our proposed versatile method for fabricating heterogeneously integrated and multilayered stretchable circuits using liquid metals (LMs). The goal of this versatile approach is to pattern LM in a manner that allows it to be exposed completely and directly accessible for integration with electronic components or other circuits, eliminating the need for VIAs. The process starts with the formation of a thin, flexible, and high mechanical modulus sacrificial layer onto a hydrophobic silane coated substrate. The sacrificial layer aims to be thin to provide flexibility and high mechanical strength to provide mechanical support when handling the fragile LM circuit elements during the fabrication process. Next, LM is patterned onto the sacrificial layer using a variety of methods leveraging its unique properties, such as its liquid form, rapid oxide formation, and wetting behavior on metals. For instance, due to LM's liquid formfactor, it can be injected into microchannels by applying a pressure gradient, calculated using the Laplace equation. Alternatively, LM can be converted into microdroplets by leveraging the rapid oxide formation on its surface, which prevents individual droplets from merging and preserves their discrete shapes for patterning with screen printing. Additionally, methods like 3D printing utilize a combination of LM's liquid properties and oxide formation to draw LM traces directly onto the substrate using a nozzle. Lastly, LM's ability to wet metals such as gold or copper can be implemented for patterning, though this approach tends to be more resource intensive and require a cleanroom environment. These methods are not exhaustive, and various combinations of LM properties can be applied to achieve the desired patterning resolution. The freedom to choose any combination of one or more methods to pattern LM in the desired resolution makes the rapid prototyping method described in this work versatile and highly applicable to diverse applications.

Once the LM is patterned, a soft and stretchable material such as an elastomer (e.g. polydimethylsiloxane (PDMS), Ecoflex, PU etc.) is cured over the LM to encapsulate and protect it from environmental factors. The entire stack, comprising of the cured PDMS, patterned LM, and the sacrificial layer, is then peeled off the substrate and flipped upside down, arranging the sacrificial layer on the top. The sacrificial layer is etched using a “direct contact etching method”, for example by placing a puddle of etchant directly onto the sacrificial layer. This direct exposure rapidly dissolves the sacrificial layer, regardless of the surface area, representing a significant improvement over conventional undercut etching method, where etching time increases significantly with the area being undercut. Following the etching process, the LM is flush with the surface of the elastomer, remains encapsulated from the bottom, and exposed only from top making it ready for integration with other circuit modules or electronic components, eliminating the need for complex fabrication to provide a VIA. This versatile method streamlines the fabrication of stretchable circuits and enhances their integration capabilities to achieve rapid prototyping of stretchable circuits.

In this patent document, we present the rapid prototyping method using poly-vinyl alcohol (PVA) as a sacrificial layer. To demonstrating the versatility of the rapid prototyping process, we implement two different methods; screen printing of LM converted into microdroplets (LMμD) and bulk LM injected into the microchannels. Lastly, we use elastomer, PDMS, to encapsulate the circuits and provide the stretchable matrix for the circuits.

### Results and Discussion

### Mechanical Robustness of PVA Sacrificial Layer

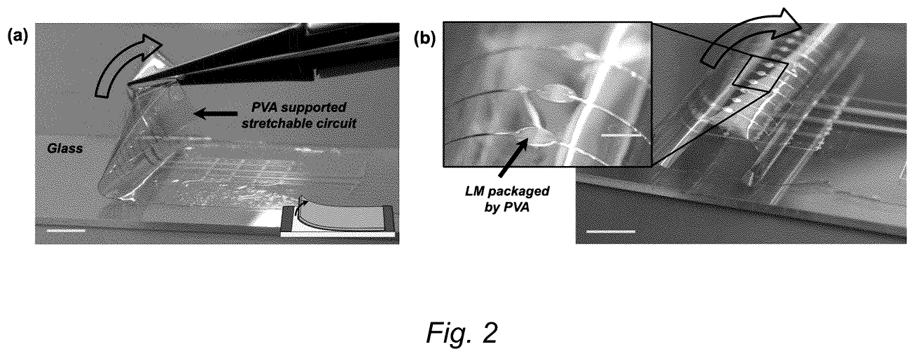

The PDMS on top of LM and PVA underneath are laminated or bonded together during the LM patterning as shown in FIG. 1(c). This lamination forms a composite of PDMS and PVA which is required to handle the fragile LM features without deformation and damage. The PDMS-LM-PVA composite was peeled off from the glass substrate as shown in FIG. 2(a). The PVA film robustly encapsulated the LM within the PDMS and prevented spillage or its removal during handling as shown in FIG. 2(b). This is attributed to the much higher modulus of PVA which was measured to be 2.37 GPa, which is ˜1000X stiffer compared to PDMS. Although the PVA layer is much thinner compared to the PDMS, its significantly higher elastic modulus shift the neutral axis of the overall device to lie within or near the PVA layer, allowing the composite structure to remain bendable and flexible. The presence of PVA also maintains the device flat without crumpling or collapsing on itself which is usually observed while handling soft materials.

### PVA Etching Time Characterization

The key step is the removal or etching of the sacrificial PVA to expose the LM wires for direct electrical contact with electronic components or other circuits realizing the fabrication of a multilayered stretchable circuit. In conventional MEMS processes, wet undercut etching is commonly employed to release devices from substrates by dissolving the sacrificial layer sandwiched between the device and substrate. For instance, a buffered oxide etch (BOE) is used to undercut the SiO₂ layer and release micromotors. Such a process could be used in the case of PDMS-LM-PVA composite layers to undercut the PVA and separate the PDMS and LM from the substrate. However, the undercut etching process is inherently slow, as it is governed by mass diffusion and constrained by various diffusion stages of the process, including the diffusion of etching species to the etching site, the etching reaction itself, and the diffusion of etched material into the bulk etchant. This slow process and significantly impacts and limits the overall process scalability to wafer-level fabrication.

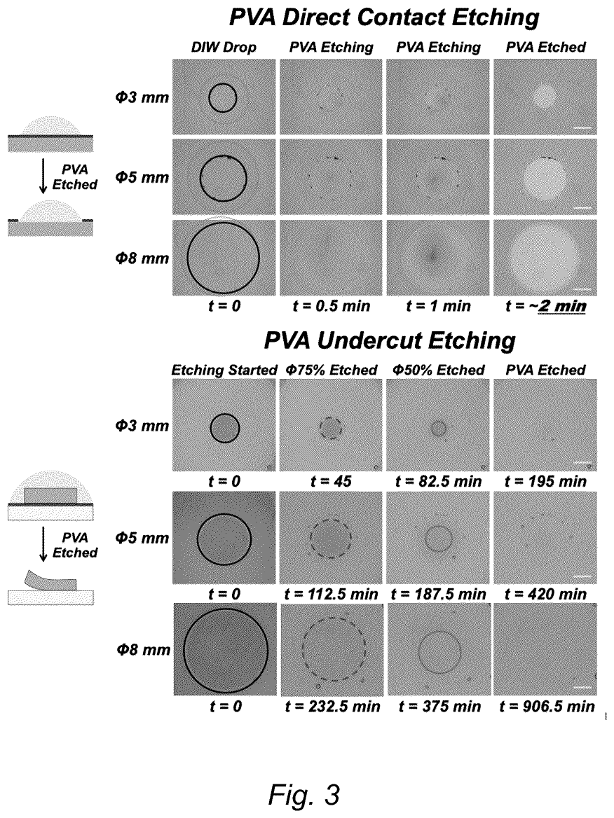

To overcome this limitation, we present a new method that leverages the properties of the PVA sacrificial layer, which can first be physically separated from the substrate and then removed through direct-contact etching. This eliminates the need for undercutting, resulting in a drastically faster fabrication and improved yield. As described earlier, the sacrificial PVA layer bonded to the PDMS and LM is first released by peeling off from the substrate, providing a rigid yet flexible backing to the soft and fragile microstructures of LM. This is followed by puddle-based direct contact etching of the PVA sacrificial layer over the entire area simultaneously by placing a large puddle of water on top. The parallel action of etching the entire PVA layer simultaneously provides the temporal advantage to this method. We characterize and compare the etching time for PVA when using the direct contact etching versus the conventional undercut method to remove the PVA and present in FIG. 3.

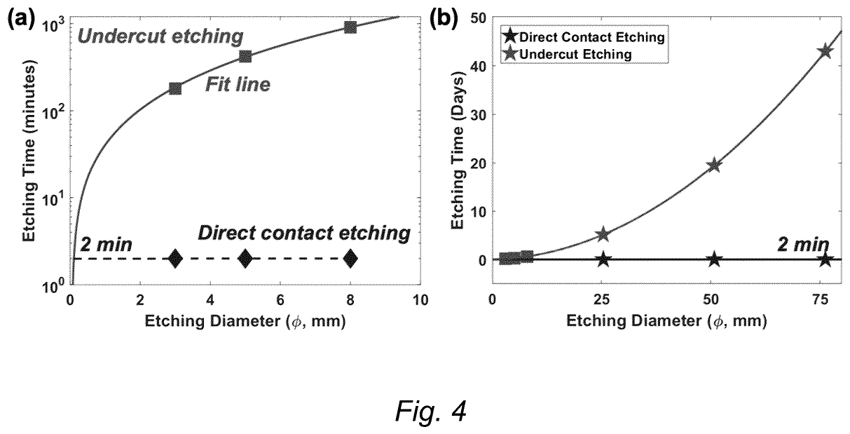

Quantification of the etching time is proceeded as follows. For direct contact etching, a shadow mask cut from the PDMS exposed an area of PVA with diameter 3, 5, and 8 mm as indicated by the solid black line in FIG. 3 (top). A puddle of water indicated by the blue line was placed on top of the exposed area to initiate the etching. The counter to characterize the etching time is initiated at the same time. The direct contact method resulted in the complete dissolution and removal of the PVA layer over entire exposed area in less than 2 minutes, as shown in FIG. 3 (top section). Maintaining the same dimensions, 3, 5, and 8 mm discs of PDMS were bonded on the PVA layer to simulate conditions for undercut etching. In contrast to the direct contact etching, the undercutting method was approximately 100, 200, and 450 times slower for areas under a 3, 5, and 8 mm disk indicated by the black line in FIG. 3 (bottom) respectively requiring significantly more time to completely delaminate the PDMS disk. The PVA etching speed in the undercut method slowed progressively as the remaining PVA volume decreased. This phenomenon can be explained by understanding the undercut region as a microfluidic channel, where water and dissolved PVA must transport back and forth between the etching site and the bulk of the etchant, i.e., DIW. As etching progresses, the distance over which dissolved PVA diffuses increases, slowing the etch rate. Image analysis of the PVA undercut progression revealed that the etching rate follows a quadratic curve, demonstrating a deceleration in apparent etching rate as the remaining PVA volume decreases. In contrast, the direct contact method allows simultaneous etching of the entire PVA layer, regardless of its size, due to uniform contact with water as shown in FIG. 4(a). In Comparison to the direct contact etching method which results in same temporal outcome regardless of the size, the undercut etching would perform poorly when scaled to a typically 3-inch diameter wafer used in MEMS fabrication as shown in FIG. 4(b). This highly parallel process enables consistent and low etching times and can be scaled to wafer-level fabrication, making it ideal for high-throughput production of stretchable electronics.

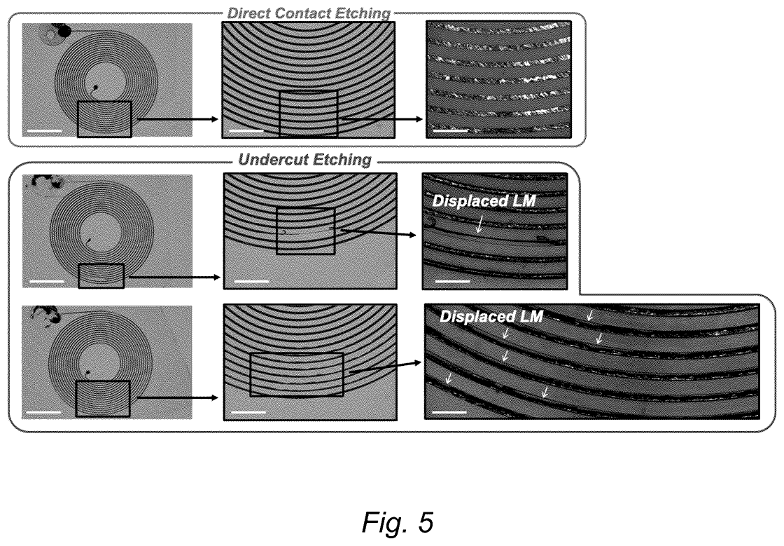

The direct-contact method for PVA etching is not only faster, resulting in substantially shorter etching time and providing a feasible pathway for scalability, but also results in a significantly higher yield of LM wires across the device compared to undercut etching. At the micrometer scale, the surface-tension force dominates over inertial forces and critically affects the stability of fluid LM encapsulated inside the PDMS. During the undercut etching process, the PVA between the PDMS-LM device and the substrate dissolves and diffuses out and is replaced by a thin, micrometer-thick layer of water. As the PVA is completely removed, the water's surface-tension-induced stiction causes the device to adhere to the substrate. As the LM device is separated from the substrate, the surface-tension-induced stiction pulls and attacks the LM, creating voids, or, worse, breaking the LM wires completely, as shown in FIG. 5, reducing the circuit yield. The surface tension induced stiction attaching the fragile LM circuits in the undercut method is due to the pressure gradient caused the surface tension of the water trapped between the LM+PDMS device and the substrate, i.e., the glass slide used here. At the micrometer scale, the surface-tension forces are substantial and need to be considered. The water trapped between the device and substrate can be assumed to be a similar thickness to the PVA, i.e., 3.5 μm. The Laplace equation calculates the inward pressure generated by the micrometer-scale water meniscus formed by the surface tension of water. For a 2-inch×2-inch device, this pressure is ˜20 kPa, which is enough to damage the LM and break the circuit, as shown in FIG. 5. In contrast, the direct DIW contact etching method uses a puddle of water without any physical cover on top of the LM wires, eliminating the surface-tension-induced stiction, preserving the LM perfectly inside the microfluidic channels, and achieving a 100% yield.

### PVA Removal and Exposed LM

The electrical circuit formed by the patterned LM and encapsulated by PDMS is fully exposed after the direct contact etching of the PVA sacrificial layer. Exposing the LM completely using the direct contact sacrificial layer etching method allows for direct pick and place approach for integrating with ICs and standard surface mount devices (SMD). This provides a practical solution for heterogenous integration and rapid prototyping of stretchable circuits similar to the mature and widely used printed circuit board technology.

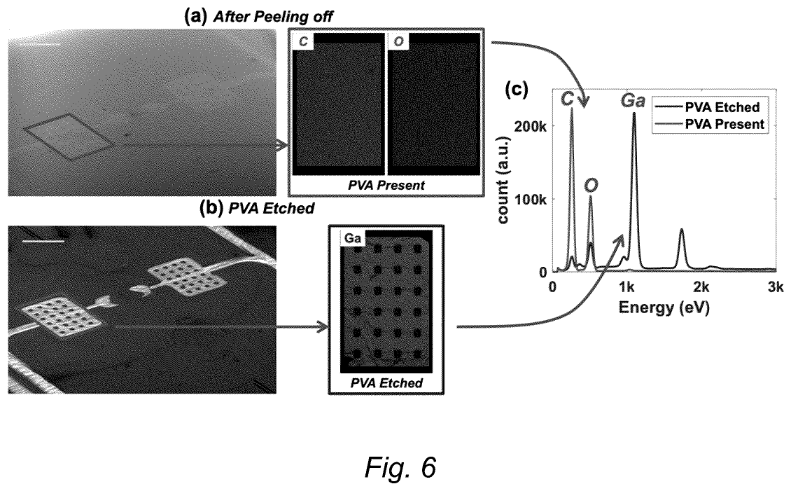

To validate the complete removal of PVA and achieve a robust electrical connection between the circuit and SMD components, we employed scanning electron microscopy (SEM) and energy-dispersive X-ray spectroscopy (EDS) to characterize the surface after PVA removal (FIG. 6). Scanning Electron Microscopy (SEM) can not only provide high-resolution imaging but distinguish between different elements when using a backscattered electron detector. Leveraging this capability, we capture and characterize the same region of the circuit both before and after the PVA etching process. The SEM images confirm the presence of PVA prior to etching, as the entire device is uniformly covered by a single material, as shown in FIG. 6(a). Since the PVA is only 3.5 μm thick, the electrons accelerated at 15 kV are able to penetrate the PVA layer and also reveal the LM circuit underneath. Post-etching, the SEM images reveal two distinct materials, PDMS and LM, as shown by the grey and brighter regions respectively and green regions respectively in FIG. 6(b) indicating the successful removal of the PVA layer. The energy dispersive spectroscopy (EDS) was also used to identify the elements and confirm the information from the visual images. The EDS before etching shows presence of carbon and oxygen corresponding to the PVA layer which is replaced by the gallium peak (FIG. 6(c)) after the etching process validating the complete removal of PVA sacrificial layer by the direct contact etching method.

The EDS characterization to analyze the material composition confirmed the complete removal of PVA. The EDS spectrum in FIG. 6(c) reveals no peaks corresponding to carbon and oxygen, key constituents of PVA after etching. Moreover, color-mapped EDS images validate the uniformity of PVA removal, with no traces of carbon and oxygen observed, further demonstrating the effectiveness of the direct contact etching process.

### Electromechanical Characterization

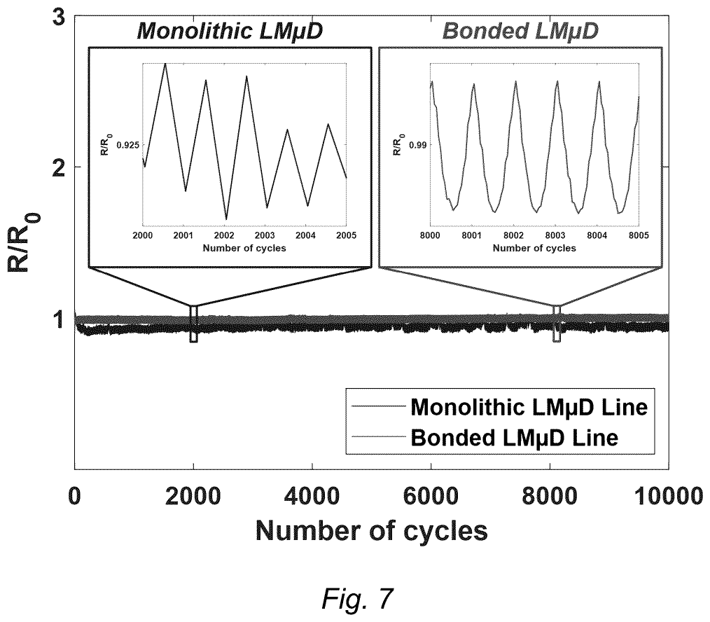

We characterized the electromechanical behavior of stretchable circuits that rely on direct contact between LMμD for integration under dynamic loading. Two devices, each consisting of screen-printed LMμD, were fabricated using the PVA as a sacrificial layer and treated with oxygen plasma (80 W, 500 mTorr, 30 s) to achieve robust bonding. Although the exposed surface contains microscopic regions of the PDMS matrix and liquid-metal droplets, the plasma treatment produces repeatable and robust covalent bonding between the exposed PDMS on the two surfaces. The device was subjected to 30% tensile strain using a tensile tester (CellScale) and connected to a SourceMeter (Keithley 2401) for simultaneous resistance measurements. The resistance remained stable, with R/R₀ maintained close to 1 throughout 10,000 stretch cycles (FIG. 7). These results are identical for a single LMμD line of same dimensions demonstrating identical performance of pristine as well as integrated LMμD circuits. These electromechanical results support the role of the PVA layer in enabling handling of fragile LM circuits and in producing defect-free stretchable devices.

### Rapid Prototyping of Stretchable Circuits

### LMμD to SMD and LMμD to LMμD Integration

Building on the characterization of the direct contact etching of PVA, we demonstrate fully functional modular LM circuits which can be easily integrated to form a functional circuit. The modularity of the LM circuits is achieved through the direct contact etching method, which exposes the LM while keeping it encapsulated within the PDMS, enabling seamless integration with other similarly fabricated modules as well as electrical components. Four LM circuit modules were designed and fabricated using the LMμD patterned using screen printing to enable integration with both SMD components and other circuit modules without requiring a VIA. It is important to note that, although simple, the design is intentionally chosen to ensure that any unstable connection between the LM circuit modules or SMD components renders the circuit non-functional. Therefore, a successfully functional circuit highlights the superior yield and effectiveness of the direct contact etching method. The integration between circuit modules is achieved through the surface contact of the exposed LMμD, which are flush with the PDMS surface. Initially, an LED was positioned at the designed location on each of the four elements and illuminated by applying a 10-mA current with a voltage limit of 3 V. The successful lighting of all four individual LEDs demonstrates successful heterogeneous integration between these soft circuits and rigid SMD components necessary to create a functional stretchable circuit. Notably, the LEDs are simply placed atop the LMμD and can be interchanged with ease using a straightforward ‘pick-and-place’ operation, highlighting the rapid prototyping capability of this method. Expanding the scope of multilayer circuit fabrication without the need for VIAs, we demonstrate similar pick and place integration between individual LM circuit modules. Each of the four modules, already integrated with an LED, was electrically connected through direct contact of the exposed LM surfaces. The detailed module integration process is illustrated in FIG. 7. The completed circuit, consisting of all four modules, was powered with a 40 mA current and a voltage limit of 6 V, successfully illuminating each of the four LEDs. This result validates the yield and efficiency of the multilayer stretchable circuit fabrication in a simple yet effective pick and place manner.

### LMμD—LM Integration

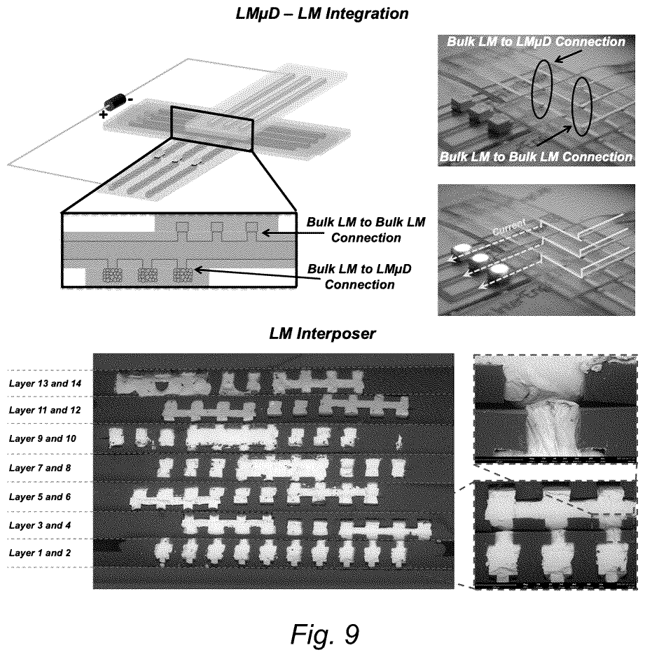

We demonstrate that the PVA method is compatible with all common liquid-metal (LM) patterning techniques. Although it eliminates the need for VIAs in two-layer stretchable electronics where circuits are integrated with SMD, it enables bidirectional VIAs required for more complex architectures beyond two layers. During LM filling of microfluidic channels, the PVA layer serves as a physical and sacrificial barrier that stops LM spillover at VIA openings. Using this approach, we fabricated microfluidic and bulk-LM modules and integrated them with liquid-metal microdroplet (LMμD) layers, demonstrating reliable interconnection between LMμD traces and bulk LM exposed at the VIA sites (FIG. 9, top). Microfluidic layers can also serve as intermediate interposers by incorporating VIAs on both the top and bottom surfaces of the channels. Combining the high resolution of microfabricated channels with bidirectional-VIA design enabled by the PVA sacrificial layer method, we achieved multilayer integration of up to 14 layers in an interposer device enabled by the PVA sacrificial layer (FIG. 9, bottom). Interposers provide electrical connections between different electronic chips, enabling high-density, low-latency interconnects for 3D heterogeneous integration in stretchable devices.

### Applications

### Stretchable Display

We demonstrate two diverse applications of the PVA sacrificial method for stretchable circuits. As described earlier, the PVA sacrificial layer is critical for release and handling of the fragile LM circuits. Furthermore, the PVA sacrificial layer is also critical to expose large area of defect free LM circuits for direct pick and place integration of SMD and other circuit modules.

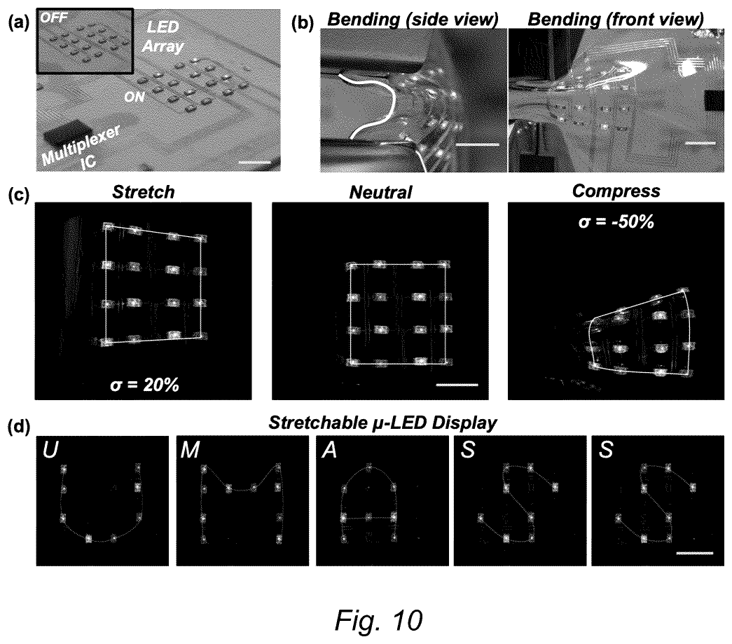

We implement microfluidics to achieve high resolution and high throughput method to pattern LM circuit like network on PVA. We choose microfluidics due to its compatibility with microfabrication processes and high-resolution patterning compared to LMμD screen printing. Additionally, microfluidic devices can be fabricated outside of the cleanroom environment and tend to be repeatable. To demonstrate the rapid prototyping capabilities as well as the scalability and uniformity of the PVA etching process over a large area, we fabricated a 30 mm×50 mm LM circuit integrated with 16 LED devices, controlled by a 16-channel multiplexer IC, as shown in FIG. 10 (a). To achieve a robust electrical connection between the rigid μLEDs and the exposed LM within the microchannels, we developed a liquid metal “soldering” technique. The LM circuit and LEDs were encapsulated with PDMS to protect the exposed LM traces, the multiplexer IC, and the LEDs. The fabricated circuit was subjected to various mechanical deformations, including bending (r=2.5 mm) (FIG. 10(b)) and tensile and compressive strains of varying degrees (FIG. 10(c)). Despite these deformations, the LM circuit remained fully functional, validating the robustness of the microfluidic-based LM fabrication process enabled by the PVA etching method. Finally, an Arduino controller was connected to the LM circuit containing the LEDs and the 16-channel multiplexer chip. The Arduino was programmed to sequentially illuminate individual LEDs in a specific pattern to display the letters “UMASS” (FIG. 10(d)). This demonstration highlights the scalability of sacrificial layer approach to expose the LM for heterogenous integration and achieving functional circuits.

### Capacitor Touch Sensor

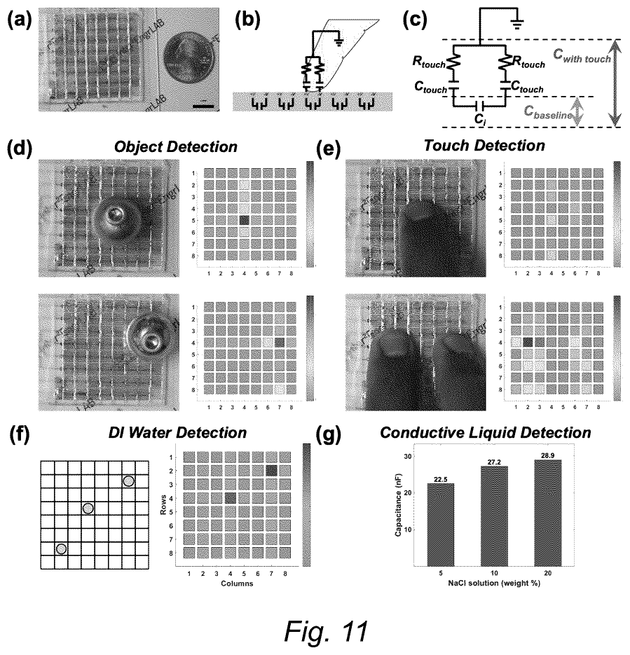

Exposing a large footprint (a few square centimeters) of LM is challenging due to its fragility but is critical for sensing applications. As the PVA sacrificial layer encapsulates the LM until the very last step in the process, a high fabrication yield is achieved through our method to expose LM for sensing applications. We demonstrate a 16 cm² LM capacitive sensor fabricated using the PVA sacrificial layer method. The sensor is designed with 64 interdigitated electrodes placed in an 8×8 array of rows and columns, forming a 16 cm² exposed LM sensing area, as shown in FIG. 11. The interdigitated electrodes consist of comb-like fingers, and two intertwined combs form each capacitive pixel. The left-side half-electrodes of the interdigitated electrode pair from all sensing pixels in a given row were connected together, and similarly, the right-side half-electrodes of all sensing pixels in a given column were connected together. In this configuration, any given capacitor sensor pixel unit can be addressed by using the two multiplexers to activate the corresponding row and column out of the total 8 rows and columns, thereby connecting the selected pixel to the impedance analyzer (Zurich Instruments, MFLI). For example, to measure the capacitance for the pixel at (4,3), an Arduino was programmed to configure both multiplexers and activate the 4th row and the 3rd column. Each pixel was scanned sequentially to detect the change in capacitance due to an object touching the sensor, human touch, or a fluid placed on the sensor. The capacitance change in the case of a human touch or object is realized as it adds a parallel capacitance in the circuit, thereby increasing the value of capacitance for that pixel, as shown in the schematic in FIG. 11(b,c). A different mechanism is implemented when the sensor interacts with a fluid. When a fluid is placed on top of the pixel, the electric field above it is distorted, resulting in a change in the capacitance value. The change in capacitance for each pixel was normalized to the baseline capacitance values without the presence of the sensed entity and plotted to identify the location of the contact. Using this method, we first measured baseline capacitance, validating the successful fabrication of a densely packed and defect-free sensor. We use this sensor to detect the location of a metal ball (FIG. 11(d)) within the sensor space as well as to sense human touch contact (FIG. 11(e)). The sensor accurately exhibits the change in capacitance, identifying the various locations where the metal ball is placed. Similarly, the sensor is capable of detecting multiple touches. This technology demonstrates a proof of concept for touch sensing and haptics, which is critical for enabling soft robotics. We also explore the use of such a sensor array to identify the presence of fluid by placing a few drops of deionized water (10 μL), as shown in FIG. 11(f). The response of the sensor, in terms of the measured capacitance, was also found to be sensitive to the conductivity of the fluid. The measured capacitance increased for solutions with higher conductivity resulting from increasing concentrations of sodium chloride solution (FIG. 11(g)). The densely packed capacitor sensor over a 16 cm2 footprint validates the capability of the implemented PVA sacrificial layer to successfully maintain and encapsulate LM and allow robust handing of LM during the fabrication steps resulting in superior mechanical and electrical yield.

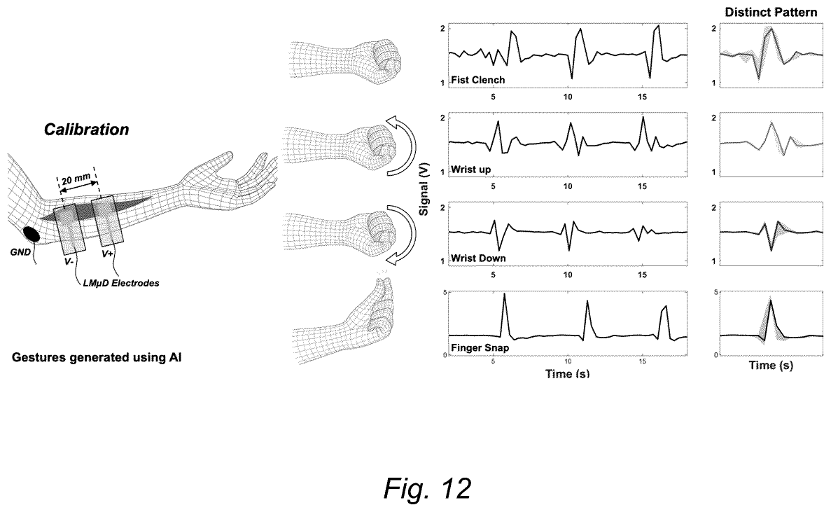

We also implemented the physical-sacrificial-layer strategy to demonstrate the application of LMμD electrodes in surface electromyography (sEMG). LMμD electrodes were prepared by screen printing and placed on the extensor carpi radialis brevis muscle, as shown in FIG. 12. A continuous sEMG signal was acquired to record the electrical activity in the muscle during various movements of the palm and wrist joint using an industrial amplifier circuit with a gain of 10. The sEMG signal exhibited four distinct patterns when the palm was clenched into a fist, the fist was moved up, the fist was moved down, and, lastly, the fingers were snapped, as shown in FIG. 12. Compared to foam-based AgCl electrodes, the LMμD-based soft electrodes provide better compliance to the skin and therefore greater comfort in sEMG sensing and human-machine interfaces.

### Conclusion

In this patent document, we introduced a novel fabrication process for creating functional stretchable electronic circuits using a physical, water-soluble sacrificial PVA layer. While conventional undercut methods are commonly employed in MEMS for device release, we developed an alternative approach utilizing a rigid yet flexible PVA layer. This method enables robust feature release, followed by parallel etching of the sacrificial layer across the entire device. The etching time for complete removal of the PVA layer was thoroughly characterized, demonstrating an approximately 450-fold improvement in efficiency compared to the conventional undercut method for a 50 mm² area. Scanning electron microscopy (SEM) verified the complete removal of PVA, which facilitated the robust heterogeneous integration of stretchable LM circuits with electronic components and other circuit modules—eliminating the need for VIAs. Finally, the versatility of this process was shown through the rapid prototyping of large-scale stretchable circuits. This work presents a unique process flow for LM circuits, offering a simpler and more efficient approach to fabricating multilayered LM circuits without relying on complex VIA designs, thereby paving the way for advancements in stretchable electronics.

It would be appreciated by those skilled in the art that various changes and modifications can be made to the illustrated embodiments without departing from the spirit of the present invention. All such modifications and changes are intended to be within the scope of the present invention except as limited by the scope of the appended claims.

What is claimed is:

1. A method of fabricating a flexible circuit on a substrate, comprising:
(a) forming a thin, flexible base layer on the substrate;
(b) forming a circuit on the base layer, the circuit comprising a plurality of electrical wires and contacts;
(c) separating the substrate from the base layer; and
(d) removing the base layer from the circuit.

2. The method of claim 1, wherein the step of forming a circuit comprises:
(e) forming a film having a plurality of microchannels, the microchannels arrayed in the layout of a circuit;
(f) bonding the film to the substrate; and
(g) filling the microchannels with a conductive material to form electrical wires and contacts of a circuit.

3. The method of claim 1, wherein the step of forming a circuit comprises screen-printing the circuit on the base layer.

4. The method of claim 1, wherein the step of forming a circuit comprises three-dimensional printing the circuit on the base layer.

5. The method of claim 1, wherein the step of forming a circuit comprises:
forming a pre-patterned metal trace; and
using the metal trace, wetting liquid metal onto the base layer to form the circuit.

6. The method of claim 1, where the step of remover the base layer comprises dissolving the base layer.

7. The method of claim 1, further comprising attaching electrical components to the electrical wires and contacts.

8. The method of claim 1, wherein the substrate is glass.

9. The method of claim 8, wherein the glass substrate has a coating of fluorosilane.

10. The method of claim 1, wherein the base layer is formed from a water-soluble polymer.

11. The method of claim 10, wherein the water-soluble polymer is PVA.

12. The method of claim 1, wherein the circuit is formed from a material selected from the group consisting of PDMS, Ecoflex, polyurethane (PU), SEBS (Styrene-Ethylene-Butylene-Styrene), dielectric elastomers (e.g., VHB tape), silicone rubber, natural rubber, thermoplastic elastomers (TPEs), fluoroelastomers, and siloxane-urethane copolymers.

13. The method of claim 1, wherein the step of forming the base layer is through spin-coating.

14. The method of claim 2, wherein the step of forming the film is through soft lithography.

15. The method of claim 2, wherein the step of bonding the film to the base layer is through an oxygen plasma treatment.

16. The method of claim 1, wherein the circuit comprises a liquid metal.

17. The method of claim 16, wherein the liquid metal is selected from the group consisting of copper, aluminum, gallium, gold, indium, tin, silver, and alloys thereof.

18. The method of claim 2, wherein the conductive material is a liquid metal.

19. The method of claim 18, wherein the liquid metal is selected from the group consisting of copper, aluminum, gallium, gold, indium, tin, silver, and alloys thereof.

20. The method of claim 1, wherein the step of forming a circuit further comprises forming an electrical device connected to the plurality of electrical wires and contacts.

21. The method of claim 2, further comprising:
forming VIAs on top and bottom surfaces of the microchannels; and
repeating the steps (a)-(g) forming a multi-layered interposer device wherein the circuit of each layer is selectively interconnected through said VIAs.
